(19) United States
(12) Patent Application Publication
(10) Pub. No.: US 2006/0014108 A1
(43) Pub. Date: Jan. 19, 2006

(54) Resist pattern forming method based on near-field exposure, and substrate processing method and device manufacturing method using the resist pattern forming method

(75) Inventors: Toshiki Ito, Kawasaki-shi (JP); Takako Yamaguchi, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/166,103

(22) Filed: Jun. 27, 2005

(30) Foreign Application Priority Data
Jun. 28, 2004 (JP) 189694/2004(PAT.)

(51) Int. Cl. G03F 7/00

(52) U.S. Cl. 430/322

(57) ABSTRACT

Disclosed is a resist pattern forming method wherein an exposure mask with a light blocking film having a fine opening not greater than a wavelength of exposure light is placed close to a resist layer provided on a substrate and wherein exposure light is projected to the resist layer through the exposure mask, whereby the resist layer is exposed with near-field light leaking from the fine opening such that a pattern of the exposure mask is transferred to the resist layer. The method includes a resist layer forming step for forming, on the substrate, a negative type resist layer with a thickness not less than a leakage depth of the near-field light, an exposure step for exposing the negative type resist layer with the near-field light, and a development step for developing the exposed negative type resist layer by use of a developing liquid to form a pattern in a region being shallower than the thickness of the negative type resist layer.

### FIELD OF THE INVENTION AND RELATED ART

This invention relates to a resist pattern forming method based on near-field exposure, and also to a substrate processing method and a device manufacturing method using the resist pattern forming method. More particularly, the invention concerns techniques related to a method of forming a resist pattern using a negative type resist.

In the fields of various electronic devices such as semiconductor devices, for example, which need microprocessing procedures, because of requirements for further enlargement of device density and integration, the pattern size has to be miniaturized more and more. One of the semiconductor manufacturing processes which plays an important role for formation of an extraordinarily fine pattern is a photolithographic process.

The photolithographic process is currently carried out on the basis of reduction projection exposure. The resolution thereof is restricted by diffraction limits of light, and generally it is about one-third of the wavelength of a light source used. Hence, the wavelength for exposure has been shortened such as, for example, by using an excimer laser as an exposure light source. Microprocessing of about 100 nm order has currently been enabled. Although the photolithography has been adapted to further miniaturization, shortening of the wavelength of light sources have raised many problems such as bulkiness of apparatus, development of lenses usable in shortened wavelengths, cost of apparatus, cost of usable resist materials, and so on.

As an attempt to overcoming these problems, proposals have been made in regard to means that enables microprocessing of 0.1 μm and under, such as exposure apparatuses using a scanning near-field optical microscope (SNOM) (Japanese Laid-Open Patent Application, Publication No. 7-106229) and exposure apparatuses using near-field light leaking from a photomask with a light blocking material having fine openings narrower than the wavelength of a light source (U.S. Pat. No. 6,171,730).

For example, Japanese Laid-Open Patent Application, Publication No. 7-106229 proposes a near-field exposure apparatus in which a mask being resiliently deformable in a direction of the normal to the mask surface is closely contacted to a resist, and in which, on the basis of near-field light leaking from a fine-opening pattern of a size not greater than 100 nm formed on the mask surface, local exposure beyond the limits of wavelength of light is carried out to an article to be exposed. According to this near-field optical lithography, a spatial resolution of nanometer order can be accomplished without restrictions by diffraction limits of light.

In the near-field optical lithography shown in U.S. Pat. No. 6,171,730, a mask with a light blocking film having fine openings not greater than the wavelength size is placed close to an image forming layer, and the exposure is carried out by use of near-field light leaking from the fine openings as light is projected thereto. In this lithographic system, the intensity of near-field light decreases exponentially with the distance from the fine openings. Thus, there is a tendency that the depth with which the light intensity contrast necessary for obtaining development contrast of a resist becomes shallow. This leads to a possibility of deficit of aspect ratio through a conventional single-layer resist process. Higher-aspect pattern formation is therefore required.

### SUMMARY OF THE INVENTION

It is accordingly an object of the present invention to provide a resist pattern forming method based on near-field exposure by which a pattern of high aspect can be formed.

It is another object of the present invention to provide a substrate processing method and/or a device manufacturing method using such resist pattern forming method.

In accordance with an aspect of the present invention, there is provided a resist pattern forming method wherein an exposure mask with a light blocking film having a fine opening not greater than a wavelength of exposure light is placed close to a resist layer provided on a substrate and wherein exposure light is projected to the resist layer through the exposure mask, whereby the resist layer is exposed with near-field light leaking from the fine opening such that a pattern of the exposure mask is transferred to the resist layer, said method comprising the steps of: forming, on the substrate, a negative type resist layer with a thickness not less than a leakage depth of the near-field light; exposing the negative type resist layer with the near-field light; and developing the exposed negative type resist layer by use of a developing liquid to form a pattern in a region being shallower than the thickness of the negative type resist layer.

In accordance with another aspect of the present invention, there is provided a resist pattern forming method based on near-field exposure, said method comprising: forming a layer having oxygen plasma etching resistance, upon a resist layer having a pattern formed thereon in accordance with a resist pattern forming method as recited above; removing, by back etching, a portion of the oxygen plasma etching resistance layer other than the portion where the pattern is formed; and removing, by oxygen plasma etching, the resist layer while using, as a mask, the oxygen plasma etching resistance layer remaining in the portion where the pattern is formed.

In accordance with a further aspect of the present invention, there is provided a substrate processing method, including a processing step for processing a substrate, having a pattern formed in accordance with a resist pattern forming method as recited above, on the basis of one of dry etching, wet etching, metal vapor deposition, lift-off and plating.

In accordance with a yet further aspect of the present invention, there is provided a device manufacturing method, comprising the steps of: preparing an exposure mask having a pattern based on a device design; and forming a pattern on a substrate for device manufacture, in accordance with a processing method as recited above.

Briefly, in accordance with the present invention, on the basis of near-field lithography using a negative type resist, a resist pattern forming method which is based on near-field exposure and which enables high-aspect pattern formation as well as a substrate processing method and a device manufacturing method using such resist pattern forming method, can be accomplished.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIGS. 1A-1E are schematic views for explaining a resist pattern forming method based on near-field exposure and using a negative type resist, in an embodiment of the present invention.

FIG. 2 is a schematic view of a light intensity profile in near-field mask exposure, for explaining an embodiment of the present invention.

### DESCRIPTION OF THE PREFERRED EMBODIMENTS

Preferred embodiments of the present invention, for a resist pattern forming method based on near-field exposure and using a negative type resist, will now be described.

Initially, as regards a substrate to be processed, a wide variety of materials may be used. Examples are a semiconductor substrate such as Si, GaAs, Inp, etc., an insulative substrate such as glass, quartz, BN, etc., and a substrate made of any one of these materials and having a film thereon being made of one or more of resist, metal, oxide, nitride and the like. As regards a negative type resist material, usable examples are acid catalyst condensation bridge (chemical amplification) type resist, optical cationic polymerization type resist, optical radical polymerization type resist, polyhydroxystyrene-bisazide type resist, cyclized rubber-bisazide type resist, polycinnamic acid vinyl, etc. From the standpoint of sensitivity, acid catalyst condensation bridge type resist is particularly preferable.

The resist coating can be done by use of known coating device and method such as spin coater, dip coater, or roller coater, for example. As regards the film thickness, it can be determined comprehensively while taking into account the processing depth of a backing substrate, plasma etching resistance of the resist material used, intensity profile of near-field light, and so on. Generally, the resist material should preferably be applied to provide a thickness of 50-300 nm after pre-baking.

Prior to the resist coating, one or more high boiling point solvents may be added to the resist in order to make the thickness after the pre-baking thinner. Examples of such solvents are benzyl ethyl ether, di-n-hexyl ether, diethylene glycol monomethyl ether, diethylene glycol monoethyl ether, acetonyl acetone, isophorone, capronic acid, caprylic acid, 1-octanol, 1-nonanol, benzyl alcohol, benzyl acetate, benzonic ethyl, diethyl oxalate, diethyl maleate, Y-butyrolacton, ethylene carbonate, propylene carbonate, and ethylene glycol monophenyl ether acetate.

The resist coating film is pre-baked at a temperature of 80-150° C., more preferably, 80-110° C. The pre-baking may be done by use of heating means such as hot plate or hot air dryer, for example.

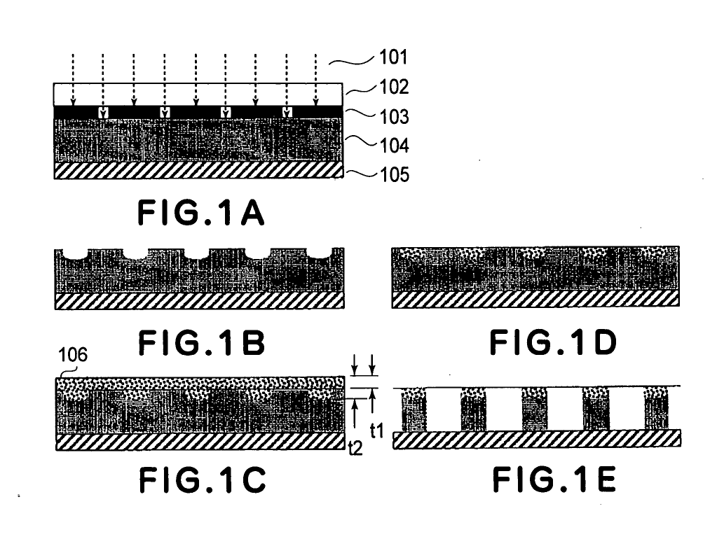

Next, referring to the schematic views of FIGS. 1A-1E, a resist pattern forming method based on near-field mask exposure in an embodiment of the present invention will be explained.

First of all, a negative type resist layer 104 is formed on a workpiece substrate 105, with a thickness not less than the leakage depth of near-field light. Subsequently, as a near-field exposure mask, a mask that comprises a mask base material 102 and a light blocking film 103 with small openings, formed on the mask base material, is used. Specifically, the light blocking film 103 and the negative type resist layer 104 are brought into close to each other up to a region where near-field light exists.

As exposure light 101 is projected to the mask base material 102 from a side remote from the light blocking film 103, near-field light is produced around the fine openings. As regards the light source of exposure light, it may be a known light source such as, for example, carbon arc lamp, mercury vapor arc lamp, high pressure Hg lamp, xenon lamp, YAG laser, Ar ion laser, semiconductor laser, F2 excimer laser, ArF excimer laser, KrF excimer laser, visible light, etc. A single light source may be used, or plural light sources may be used in combination.

By means of this near-field light, a latent image is formed in the negative type resist layer 104 (FIG. 1A). After this, if necessary, a heating process after exposure may be carried out. The heating process after exposure, if it is to be done, may be carried out at a temperature of 80-150° C. Then, by developing the resist, a pattern such as shown in FIG. 1B is produced on the negative type resist layer 104.

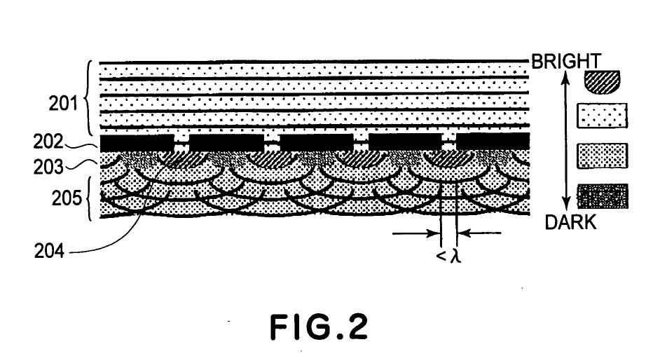

Here, referring to the schematic view of FIG. 2, showing the light intensity profile of near-field mask exposure, the principle of how a pattern such as shown in FIG. 1B can be formed will be explained.

Here, denoted in FIG. 2 at 201 is exposure light, and denoted at 202 is a light blocking film. Denoted at 203 is a near-field pattern region, and denoted at 204 is near-field light. Denoted at 205 is propagation light having been converted from the near-field light.

Just underneath the opening of the light blocking film, near-field light 204 leaking up to a depth of about 100 nm, at the maximum, is produced. The near-field light thus produced is converted again into propagation light 205, and it reaches the lower portion of the resist film which can not be reached by the near-field light. Since the propagation light 205 has a directivity weaker than the exposure light 201, it can reach the lower portion of the light blocking film as well. On the other hand, just underneath the light blocking film, due to pseudo phase shift effect wherein a shift of π occurs between the phases of surface plasmon propagated from adjacent openings, a dark area is necessarily produced.

For this reason, in the near-field mask exposure using a negative type resist, by appropriately setting the exposure time, it is assured that in the near-field pattern region 203 only a portion thereof just underneath the light blocking film is not set but solved into a developing liquid, such that a patter as shown in FIG. 1B is produced. Namely, up to the leaking depth of the near field light, a pattern that reflects the mask pattern is formed and, on the other hand, in a portion deeper than the leakage depth, the resist is overall set by the propagation light 205 having been converted from the near field light and having been diffused, whereby a pattern such as shown in FIG. 1B is produced.

Next, a process for increasing the aspect of a pattern formed on the upper portion of the resist layer in the manner described above, will be explained.

First of all, an oxygen plasma etching resisting film is formed upon the resist layer having a pattern formed thereon (FIG. 1C).

The thickness of the oxygen plasma etching resisting layer should be one by which a step (surface step) that defines the resist pattern can be covered sufficiently.

As regards the material of oxygen plasma etching resisting film, any material is applicable provided that it has a resistance to oxygen plasma etching higher than that of the resist. However, Si compound such as SiO₂ as well as TiO₂ are particularly preferable. The oxygen plasma etching resisting film may be formed in accordance with variable methods such as sol-gel method, sputtering method, CVD method, etc.

Where an oxygen plasma etching resisting film is formed in accordance with sol-gel method, in order to improve the solvent resistance of the negative type resist, preferably it should be heated at a temperature of 110-250° C.

Subsequently, an etch-back process for the oxygen plasma etching resisting film is carried out to remove the oxygen plasma etching resisting film in a portion other than the resist pattern recess portion, whereby a structure such as shown in FIG. 1D is obtainable.

Regarding the etch-back depth, it should be not less than t₁ but not greater than t₂ (FIG. 1C), and yet it should be made close to t₁ as much as possible.

Either wet etching or dry etching may be applicable to the etch-back process. However, dry etching is more suitable to formation of a fine pattern, and thus it is preferable.

As regards wet etching agent, usable examples are hydrofluoric acid aqueous solution, ammonium fluoride aqueous solution, phosphoric acid aqueous solution, acetic acid aqueous solution, nitride acid aqueous solution, cerium nitrate ammonium aqueous solution, etc., and they can be used in accordance with the object of etching.

As regards dry etching gas, usable examples are CHF₃, CF₄, C₂, F₆, SF₆, CCl₄, BCl₃, Cl₂, HCl, H₂, Ar, etc. These gases may be used in combination as required.

After the etch-back process, while the remaining oxygen plasma etching resisting layer is used as a mask, an oxygen plasma etching process is carried out to the resist layer, whereby a resist pattern such as shown in FIG. 1E is obtainable. As regards an oxygen containing gas to be used for the oxygen plasma etching, usable examples are oxygen itself, a mixed gas of oxygen and an inactive gas such as argon, for example, and a mixed gas of oxygen and carbon monoxide, carbon dioxide, ammonia, dinitrogen monoxide, or sulfur dioxide, etc.

By using a resist pattern having been formed in the manner described above as a mask, one of dry etching, wet etching, metal vapor deposition, lift-off and plating is carried out to process a substrate, whereby a desired device can be produced from it.

In accordance with a substrate processing method such as described above, various specific devices can be produced. Examples are (1) a semiconductor device, (2) a quantum dot laser device where the method is used for production of a structure in which GaAs quantum dots of 50 nm size are arrayed two-dimensionally at 50 nm intervals, (3) a sub wavelength element (SWS) structure having antireflection function where the method is used for production of a structure in which conical SiO₂ structures of 50 nm size are arrayed two-dimensionally at 50 nm intervals on a SiO₂ substrate, (4) a photonic crystal optics device or plasmon optical device where the method is used for production of a structure in which structures of 100 nm size, made of GaN or metal, are arrayed two-dimensionally and periodically at 100 nm intervals, (5) a biosensor or a micro-total analyzer system (μTAS) based on local plasmon resonance (LPR) or surface enhancement Raman spectrum (SERS) where the method is used for production of a structure in which Au fine particles of 50 nm size are arrayed two-dimensionally upon a plastic substrate at 50 nm intervals, (6) a nano-electromechanical system (NEMS) device such as SPM probe, for example, where the method is used for production of a radical structure of 50 nm size or under, to be used in a scanning probe microscope (SPM) such as a near-field optical microscope, an atomic force microscope, and a tunnel microscope, and the like.

Next, an example of the present invention will be explained. This example is a specific example wherein an embodiment of a resist pattern forming method of the present invention such as described above is applied. It will be explained with reference to FIGS. 1A-1E.

First of all, onto a silicon substrate, a negative type resist consisting of polyhydroxystyrene and melamine resin as a major ingredient is applied by use of a spin coater, so that the film thickness thereof after the pre-baking becomes equal to 150 nm. Thereafter, pre-baking is carried out on a hot plate, at a temperature of 90° C. for 60 seconds.

The mask comprises a photomask having a mask base material made from a silicon nitride thin film and supported by a silicon substrate, and a Cr layer having been vapor deposited on the mask base material. A transfer original pattern (fine pattern) of a light blocking film has been drawn by use of an electron beam pattern drawing apparatus upon the Cr layer of the photomask. The opening width of this mask is made not greater than the exposure wavelength. The photomask described above is placed closely to the image forming photoresist layer on the substrate, throughout the entire surface thereof and, in this state, light from an Hg lamp having an i-line bandpass filter is projected, whereby the exposure is carried out. Then, upon a hot plate, the heating process after exposure is carried out at a temperature of 60° C. for 60 seconds. Then, it is cooled to the room temperature and, thereafter, the resist is developed by use of 2.38% aqueous solution of tetramethylammonium hydroxide, whereby a resist pattern of about 50 nm depth having the same pitch as the photomask is obtainable.

The substrate is then heated by a hot plate at 200° C. for 10 minutes and, after that, 10 weight percent methyl isobutyl ketone solution of hydrogen silsesquioxane is applied onto the resist by using a spin coater. Subsequently, the substrate is heated by a hot plate at 110° C. for 90 seconds. By coating a flat Si substrate to provide a thickness of about 100 nm, an oxygen plasma etching resisting layer can be formed substantially without being influenced by a surface step of about 50 nm size of the resist pattern.

Subsequently, the hydrogen silsesquioxane layer is etched by about 100 nm, by using CHF₃ gas, whereby a structure such as shown in FIG. 1D is obtained. Thereafter, oxygen plasma etching is carried out while using, as a mask, the hydrogen silsesquioxane film remaining in the recess portion of the pattern, whereby a resist pattern such as shown in FIG. 1E, having a height of 150 nm, is obtained.

While the invention has been described with reference to the structures disclosed herein, it is not confined to the details set forth and this application is intended to cover such modifications or changes as may come within the purposes of the improvements or the scope of the following claims.

This application claims priority from Japanese Patent Application No. 2004-189694 filed Jun. 28, 2004, for which is hereby incorporated by reference.

What is claimed is:

1. A resist pattern forming method wherein an exposure mask with a light blocking film having a fine opening not greater than a wavelength of exposure light is placed close to a resist layer provided on a substrate and wherein exposure light is projected to the resist layer through the exposure mask, whereby the resist layer is exposed with near-field light leaking from the fine opening such that a pattern of the exposure mask is transferred to the resist layer, said method comprising the steps of:
forming, on the substrate, a negative type resist layer with a thickness not less than a leakage depth of the near-field light;
exposing the negative type resist layer with the near-field light; and
developing the exposed negative type resist layer by use of a developing liquid to form a pattern in a region being shallower than the thickness of the negative type resist layer.

2. A method according to claim 1, wherein, in said exposure step, up to the leakage depth of the near-field light, a pattern that reflects the mask pattern is formed on the basis of a predetermined exposure amount, and wherein, in a portion with a depth greater than the leakage depth, the resist material is overall set with propagation light having been converted from the near-field light and having been diffused.

3. A method according to claim 1, further comprising a heating step for heating the substrate after said exposure step and before said development step.

4. A method according to claim 1, wherein the negative type resist is a chemical amplification type resist.

5. A resist pattern forming method based on near-field exposure, said method comprising:
forming a layer having oxygen plasma etching resistance, upon a resist layer having a pattern formed thereon in accordance with a resist pattern forming method as recited in claim 1;
removing, by back etching, a portion of the oxygen plasma etching resistance layer other than the portion where the pattern is formed; and
removing, by oxygen plasma etching, the resist layer while using, as a mask, the oxygen plasma etching resistance layer remaining in the portion where the pattern is formed.

6. A method according to claim 5, wherein the oxygen plasma etching resistance layer contains silicon atoms or titanium atoms.

7. A method according to claim 5, further comprising a heating step for heating the substrate before said oxygen plasma etching resistance layer forming step.

8. A method according to claim 5, wherein the oxygen plasma etching resistance layer is formed in accordance with a sol-gel method.

9. A substrate processing method, including a processing step for processing a substrate, having a pattern formed in accordance with a resist pattern forming method as recited in claim 5, on the basis of one of dry etching, wet etching, metal vapor deposition, lift-off and plating.

10. A device manufacturing method, comprising the steps of:
preparing an exposure mask having a pattern based on a device design; and
forming a pattern on a substrate for device manufacture, in accordance with a processing method as recited in claim 9.
